(19) United States
(12) Patent Application Publication
(10) Pub. No.: US 2023/0232640 A1
(43) Pub. Date: Jul. 20, 2023

(54) VARIABLE RESISTANCE MEMORY DEVICE

(71) Applicant: SAMSUNG ELECTRONICS CO., LTD., SUWON-SI (KR)

(72) Inventors: JINWOO LEE, SEOUL (KR); DONGHO AHN, HWASEONG-SI (KR); DONGGEON GU, HWASEONG-SI (KR); WONJUN PARK, SEOUL (KR); CHANGYUP PARK, HWASEONG-SI (KR)

(21) Appl. No.: 17/931,116

(22) Filed: Sep. 9, 2022

(30) Foreign Application Priority Data
Jan. 14, 2022 (KR) 10-2022-0006104

(51) Int. Cl. H01L 27/24; H01L 45/00

(52) U.S. Cl. CPC H01L 27/249; H01L 45/1683

(57) ABSTRACT

A variable resistance memory device includes a stacking pattern disposed on a substrate, a vertical structure extends in a first direction, which is perpendicular to a top surface of the substrate, and penetrates the stacking pattern, and a horizontal conductive line disposed adjacent to the stacking pattern and extending in a second direction that is parallel to the top surface of the substrate. The vertical structure includes a vertical conductive line penetrating the stacking pattern, a variable resistance element enclosing the vertical conductive line, and a selection element interposed between the vertical conductive line and the variable resistance element. Each of the vertical conductive line, the variable resistance element, and the selection element extends in the first direction. The stacking pattern is electrically connected to the horizontal conductive line and extends along the horizontal conductive line and in the second direction.

### CROSS-REFERENCE TO RELATED APPLICATIONS

This U.S. non-provisional patent application claims priority under 35 U.S.C. § 119 to Korean Patent Application No. 10-2022-0006104, filed on Jan. 14, 2022, in the Korean Intellectual Property Office, the entire contents of which are hereby incorporated by reference.

### TECHNICAL FIELD

The present disclosure relates to a variable resistance memory device, and in particular, to a variable resistance memory device having memory cells that are three-dimensionally arranged.

### DISCUSSION OF THE RELATED ART

Modern semiconductor devices are more highly integrated than in years past. In the case of two-dimensional or planar semiconductor devices, since their integration is mainly determined by the area occupied by a unit memory cell, integration is greatly influenced by the level of a fine pattern forming technology. This is to say, finer feature sizes is the principal way in which greater integration is achieved in two-dimensional semiconductor devices in which integrated circuits are not stacked vertically. However, extremely expensive equipment is needed to reduce a feature size of patterns. To overcome such a limitation, a three-dimensional semiconductor device including three-dimensionally-arranged memory cells has been proposed. In addition, next-generation semiconductor memory devices, such as a magnetic random access memory (MRAM) and a phase-change random access memory (PRAM), are being developed in order to meet an increasing demand for a semiconductor memory device with high performance and low power consumption properties.

### SUMMARY

A variable resistance memory device includes a stacking pattern on a substrate, a vertical structure extended in a first direction, which is perpendicular to a top surface of the substrate, and penetrating the stacking pattern, and a horizontal conductive line disposed adjacent to the stacking pattern and extended in a second direction parallel to the top surface of the substrate. The vertical structure includes a vertical conductive line penetrating the stacking pattern, a variable resistance element enclosing the vertical conductive line, and a selection element interposed between the vertical conductive line and the variable resistance element. Each of the vertical conductive line, the variable resistance element, and the selection element extends in the first direction. The stacking pattern is electrically connected to the horizontal conductive line and extends along the horizontal conductive line and in the second direction.

A variable resistance memory device includes stacking patterns on a substrate, the stacking patterns including a first stacking pattern and a second stacking pattern, which is spaced apart from the first stacking pattern in a first direction that is perpendicular to a top surface of the substrate, a vertical structure extended in the first direction to penetrate the stacking patterns, and horizontal conductive lines extended in a second direction, which is parallel to the top surface of the substrate, and disposed adjacent to the stacking patterns, respectively. The vertical structure includes a vertical conductive line penetrating the stacking patterns, a variable resistance element enclosing the vertical conductive line, and a selection element interposed between the vertical conductive line and the variable resistance element. Each of the vertical conductive line, the variable resistance element, and the selection element extends in the first direction. A first thickness of the first stacking pattern in the first direction is different from a second thickness of the second stacking pattern in the first direction.

A variable resistance memory device includes stacking patterns, which are stacked on a substrate and are spaced apart from each other in a first direction that is perpendicular to a top surface of the substrate, and a vertical structure, which extends in the first direction and penetrating the stacking patterns. The vertical structure includes a vertical conductive line penetrating the stacking patterns, a variable resistance element enclosing the vertical conductive line, and a selection element interposed between the vertical conductive line and the variable resistance element. Each of the vertical conductive line, the variable resistance element, and the selection element extends in the first direction. Each of the stacking patterns extends in a second direction parallel to the top surface of the substrate and includes a two-dimensional material.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a perspective view schematically illustrating a variable resistance memory device according to an embodiment of the inventive concept;

FIGS. 2 to 4 are plan views, which are respectively taken at levels AA′, BB′, and CC′ of FIG. 1 illustrating a variable resistance memory device according to an embodiment of the inventive concept;

FIGS. 5A and 6A are cross-sectional views, each of which is taken along a line I-I′ of FIG. 2;

FIGS. 5B and 6B are cross-sectional views, each of which is taken along a line II-II′ of FIG. 2;

FIGS. 7 to 15 are diagrams illustrating a method of fabricating a variable resistance memory device according to an embodiment of the inventive concept, FIGS. 7, 10, and 13 are plan views taken at the level AA′ of FIG. 1, FIGS. 8, 11, and 14 are cross-sectional views, which are respectively taken along lines I-I′ of FIGS. 7, 10, and 13, and FIGS. 9, 12, and 15 are cross-sectional views, which are respectively taken along lines II-II′ of FIGS. 7, 10, and 13;

FIGS. 16 and 17 are cross-sectional views, each of which is taken along the line I-I′ of FIG. 2 illustrating a variable resistance memory device according to an embodiment of the inventive concept;

FIG. 18 is a plan view, which is taken at the level BB′ of FIG. 1 illustrating a variable resistance memory device according to an embodiment of the inventive concept;

FIGS. 19 and 20 are cross-sectional views, which are respectively taken along lines I-I′ and II-II′ of FIG. 18 illustrating a method of fabricating the variable resistance memory device of FIG. 18;

FIG. 21 is a plan view, which is taken at the level BB′ of FIG. 1 illustrating a variable resistance memory device according to an embodiment of the inventive concept;

FIGS. 22 and 23 are cross-sectional views, which are respectively taken along lines I-I′ and II-II′ of FIG. 21 illustrating a method of fabricating the variable resistance memory device of FIG. 21;

FIG. 24 is a cross-sectional view, which is taken along the lines I-I′ of FIGS. 2 and 4 illustrating a variable resistance memory device according to an embodiment of the inventive concept; and

FIGS. 25 to 27 are cross-sectional views illustrating a method of fabricating the variable resistance memory device of FIG. 24.

### DETAILED DESCRIPTION OF THE DRAWINGS

Example embodiments of the inventive concepts will now be described more fully with reference to the accompanying drawings.

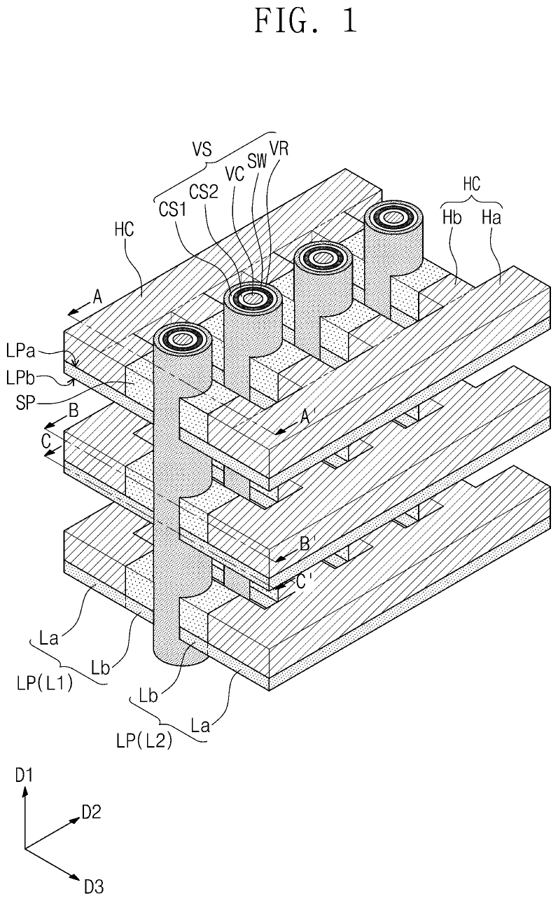

FIG. 1 is a perspective view schematically illustrating a variable resistance memory device according to an embodiment of the inventive concept.

Referring to FIG. 1, a vertical structure VS and a stacking pattern LP may be provided, and here, the stacking pattern LP may cross the vertical structure VS. The vertical structure VS may extend in a first direction D1 to penetrate the stacking pattern LP. In an embodiment, a plurality of the vertical structures VS may be spaced apart from each other in a second direction D2 that is orthogonal to the first direction D1.

The vertical structure VS may include a vertical conductive line VC, a variable resistance element VR, and a selection element SW. The vertical conductive line VC may extend in the first direction D1 to penetrate the stacking pattern LP. The variable resistance element VR may extend in the first direction D1 and may enclose the vertical conductive line VC. As an example, the variable resistance element VR may be the outermost part of the vertical structure VS and may be in contact with the stacking pattern LP. The selection element SW may be interposed between the vertical conductive line VC and the variable resistance element VR and may extend in the first direction D1. The selection element SW may enclose an outer circumference surface of the vertical conductive line VC, and the variable resistance element VR may enclose an outer circumference surface of the selection element SW.

In an embodiment, the vertical structure VS may be circular, in a plan view. For example, all of the vertical conductive line VC, the selection element SW, and the variable resistance element VR may be circular and may be substantially concentric with each other. The vertical conductive line VC may have the smallest radius and may be disposed adjacent to a center of the vertical structure VS. The variable resistance element VR may be provided as the outermost part of the vertical structure VS to have the largest radius.

The vertical conductive line VC may be formed of or may include one or more metallic material (e.g., copper, tungsten, or aluminum) and/or metal nitride materials (e.g., tantalum nitride, titanium nitride, or tungsten nitride).

The selection element SW may be a diode or may be a device having a non-linear (e.g., S-shaped) I-V curve, based on a threshold switching phenomenon. As an example, the selection element SW may be an ovonic threshold switch (OTS) device having a bi-directional property.

In an embodiment, the selection element SW may be formed of or may include GeSe, GeS, AsSe, AsTe, AsS SiTe, SiSe, SiS, GeAs, SiAs, SnSe, and/or SnTe. In an embodiment, the selection element SW may be formed of or may include GeAsTe, GeAsSe, AlAsTe, AlAsSe, SiAsSe, SiAsTe, GeSeTe, GeSeSb, GaAsSe, GaAsTe, InAsSe, InAsTe, SnAsSe, and/or SnAsTe. In an embodiment, the selection element SW may be formed of or may include GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, eAsTeIn, GeAsTeGa, GeAsTeAl, GeAsTeTl, GeAsTeSn, and/or GeAsTeZn. In an embodiment, the selection element SW may be formed of or may include GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSEAlSn, GeAsSeTlZn, GeAsSeTlSn, and/or GeAsSeZnSn. In an embodiment, the selection element SW may be formed of or may include GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and/or GeAsSeSAlSn. The selection element SW may further include B, C, N, and/or O. The selection element SW may have a single-layered structure or a multi-layered structure, in which a plurality of layers are stacked.

The variable resistance element VR may include a material, which has a variable resistance property, and this may make it possible to use the variable resistance element VR as a data-storing element. In an embodiment, the variable resistance element VR may include a material whose phase can be changed to one of crystalline and amorphous structures, depending on its temperature. The variable resistance element VR may include a compound containing chalcogen elements (e.g., Te and Se) and/or Ge, Sb, Bi, Pb, Sn, Ag, As, S, Si, In, and/or Ga.

In an embodiment, the variable resistance element VR may be formed of or may include GeTe, GeSe, GeS, SbSe, SbTe, SbS, SbSe, SnSb, InSe, InSb, AsTe, AlTe, GaSb, AlSb, BiSb, ScSb, Ysb, CeSb, DySb, and/or NdSb. In an embodiment, the variable resistance element VR may be formed of or may include GeSbSe, AlSbTe, AlSbSe, SiSbSe, SiSbTe, GeSeTe, InGeTe, GeSbTe, GeAsTe, SnSeTe, GeGaSe, BiSbSe, GaSeTe, InGeSb, GaSbSe, GaSbTe, InSbSe, InSbTe, SnSbSe, SnSbTe, ScSbTe, ScSbSe, ScSbS, YSbTe, YSbSe, YSbS, CeSbTe, CeSbSe, CeSbS, DySbTe, DySbSe, DySbS, NdSbTe, NdSbSe, and/or NdSbS. In an embodiment, the variable resistance element VR may be formed of or may include GeSbTeS, BiSbTeSe, AgInSbTe, GeSbSeTe, GeSnSbTe, SiGeSbTe, SiGeSbSe, SiGeSeTe, BiGeSeTe, BiSiGeSe, BiSiGeTe, GeSbTeBi, GeSbSeBi, GeSbSeIn, GeSbSeGa, GeSbSeAl, GeSbSeTl, GeSbSeSn, GeSbSeZn, GeSbTeIn, GeSbTeGa, GeSbTeAl, GeSbTeTl, GeSbTeSn, GeSbTeZn, ScGeSbTe, ScGeSbSe, ScGeSbS, YGeSbTe, YGeSbSe, YGeSbS, CeGeSbTe, CeGeSbSe, CeGeSbS, DyGeSbTe, DyGeSbSe, DyGeSbS, NdGeSbTe, NdGeSbSe, and/or NdGeSbS. In an embodiment, the variable resistance element VR may be formed of or may include InSbTeAsSe, GeScSbSeTe, GeSbSeTeS, GeScSbSeS, GeScSbTeS, GeScSeTeS, GeScSbSeP, GeScSbTeP, GeSbSeTeP, GeScSbSeIn, GeScSbSeGa, GeScSbSeAl, GeScSbSeTl, GeScSbSeZn, GeScSbSeSn, GeScSbTeIn, GeScSbTeGa, GeSbAsTeAl, GeScSbTeTl, GeScSbTeZn, GeScSbTeSn, GeSbSeTeIn, GeSbSeTeGa, GeSbSeTeAl, GeSbSeTeTl, GeSbSeTeZn, GeSbSeTeSn, GeSbSeSIn, GeSbSeSGa, GeSbSeSAl, GeSbSeSTl, GeSbSeSZn, GeSbSeSSn, GeSbTeSIn, GeSbTeSGa, GeSbTeSAl, GeSbTeSTl, GeSbTeSZn, GeSbTeSSn, GeSbSeInGa, GeSbSeInAl, GeSbSeInTl, GeSbSeInZn, GeSbSeInSn, GeSbSeGaAl, GeSbSeGaTl, GeSbSeGaZn, GeSbSeGaSn, GeSbSeAlTl, GeSbSeAlZn, GeSbSeAlSn, GeSbSeTlZn, GeSbSeTlSn, and/or GeSbSeZnSn. The variable resistance element VR may further include B, C, N, O, P, Cd, W, Ti, Hf, and/or Zr.

The variable resistance element VR may have a single-layered structure or a multi-layered structure, in which a plurality of layers are stacked. In an embodiment, the variable resistance element VR may have a super lattice structure, in which a germanium-containing layer and a germanium-free layer are repeatedly stacked. In an embodiment, the variable resistance element VR may have a structure, in which GeTe and SbTe layers are repeatedly stacked.

The vertical structure VS may further include a first capping structure CS1 and a second capping structure CS2. The first capping structure CS1 may be interposed between the variable resistance element VR and the selection element SW to prevent the variable resistance element VR and the selection element SW from being in direct contact with each other. The first capping structure CS1 may prevent the variable resistance element VR from being diffused into the selection element SW or prevent the selection element SW from being diffused into the variable resistance element VR. The first capping structure CS1 may enclose the outer circumference surface of the selection element SW, and the variable resistance element VR may enclose an outer circumference surface of the first capping structure CS1. The second capping structure CS2 may be interposed between the vertical conductive line VC and the selection element SW to prevent the vertical conductive line VC and the selection element SW from being in direct contact with each other. The second capping structure CS2 may prevent the vertical conductive line VC from being diffused into the selection element SW or may prevent the selection element SW from being diffused into the vertical conductive line VC. The second capping structure CS2 may enclose the outer circumference surface of the vertical conductive line VC, and the selection element SW may enclose an outer circumference surface of the second capping structure CS2. Each of the first and second capping structures CS1 and CS2 may include carbon (C).

In an embodiment, a plurality of the stacking patterns LP may be provided at different levels in the first direction D1. The stacking pattern LP may extend in the second direction D2. The stacking pattern LP may include a first sub-stacking pattern L1, which is provided at a side of the vertical structure VS, and a second sub-stacking pattern L2, which is provided at an opposite side of the vertical structure VS. The stacking pattern LP may be divided into the first sub-stacking pattern L1 and the second sub-stacking pattern L2 by the vertical structure VS. Each of the first and second sub-stacking patterns L1 and L2 may be in contact with the variable resistance element VR of the vertical structure VS. Each of the first and second sub-stacking patterns L1 and L2 may extend in the second direction D2 orthogonal to the first direction D1. The first and second sub-stacking patterns L1 and L2 may be spaced apart from each other in a third direction D3 with the vertical structure VS interposed therebetween. The third direction D3 may be orthogonal to the first direction D1 and may be non-parallel (e.g., orthogonal) to the second direction D2.

In an embodiment, in a plan view, the stacking pattern LP may include portions protruding toward the vertical structures VS and may have a comb shape. For example, the stacking pattern LP may include a line portion La, which extends in the second direction D2, and protruding portions Lb, which extend from the line portion La toward the vertical structures VS, respectively. Each of the first and second sub-stacking patterns L1 and L2 may include the line portion La and the protruding portions Lb. Each of the protruding portions Lb may be in contact with the variable resistance element VR of a corresponding one of the vertical structures VS.

The stacking pattern LP may be formed of or may include one or more two-dimensional materials. The two-dimensional material may be a crystalline material composed of a single atomic layer. In an embodiment, the stacking pattern LP may be a single layer including a two-dimensional material. In an embodiment, the stacking pattern LP may be formed of or may include one or more two-dimensional materials and may be composed of a plurality of layers. For example, the two-dimensional material of the stacking pattern LP may include graphene and/or transition metal dichalcogenides (TMD).

The stacking pattern LP may be in contact with the variable resistance elements VR of the vertical structures VS. For example, each of the first and second sub-stacking patterns L1 and L2 may be in contact with the variable resistance elements VR of the vertical structures VS. A resistance value of each of the variable resistance elements VR may vary depending on a degree of crystallization in a region in contact with the stacking pattern LP. The higher the degree of crystallization of the variable resistance element VR, the lower the resistance value, and the lower the degree of crystallization, the higher the resistance value. The degree of crystallization (i.e., the resistance value) of the variable resistance element VR may be controlled by a heat energy produced when an electric pulse is applied thereto. The control process may correspond to an operation of writing data in the variable resistance memory device. The resistance value of the variable resistance memory device may be measured, and the measurement process may correspond to an operation of reading data in variable resistance memory device.

A horizontal conductive line HC may be provided adjacent to the stacking pattern LP. The horizontal conductive line HC may be in contact with a top or bottom surface LPa and LPb of the stacking pattern LP and may be electrically connected to the stacking pattern LP. In an embodiment, a plurality of the horizontal conductive lines HC may be provided. Each of the horizontal conductive lines HC may be provided near and electrically connected to one of the first and second sub-stacking patterns L1 and L2.

The horizontal conductive line HC may extend in the second direction D2. As an example, the horizontal conductive line HC may include a line portion Ha, which extends in the second direction D2, and protruding portions Hb, which are respectively extended from the line portion Ha toward the vertical structures VS, as shown in FIG. 1. The horizontal conductive line HC may be vertically overlapped with a portion of the stacking pattern LP.

The horizontal conductive line HC may be formed of or may include a metallic material (e.g., copper, tungsten, or aluminum) and/or metal nitride materials (e.g., tantalum nitride, titanium nitride, or tungsten nitride).

A sacrificial pattern SP may be interposed between the horizontal conductive line HC and the vertical structure VS. The horizontal conductive line HC may be horizontally spaced apart from the vertical structure VS with the sacrificial pattern SP interposed therebetween. The sacrificial pattern SP may be in contact with one of the top and bottom surfaces LPa and LPb of the stacking pattern LP. In an embodiment, the sacrificial pattern SP may be provided on the first sub-stacking pattern L1 to separate the horizontal conductive line HC from the sacrificial pattern SP. In an embodiment, the sacrificial pattern SP may be provided on the second sub-stacking pattern L2 to separate the horizontal conductive line HC from the sacrificial pattern SP. In an embodiment, the sacrificial pattern SP may be formed of or may include silicon nitride.

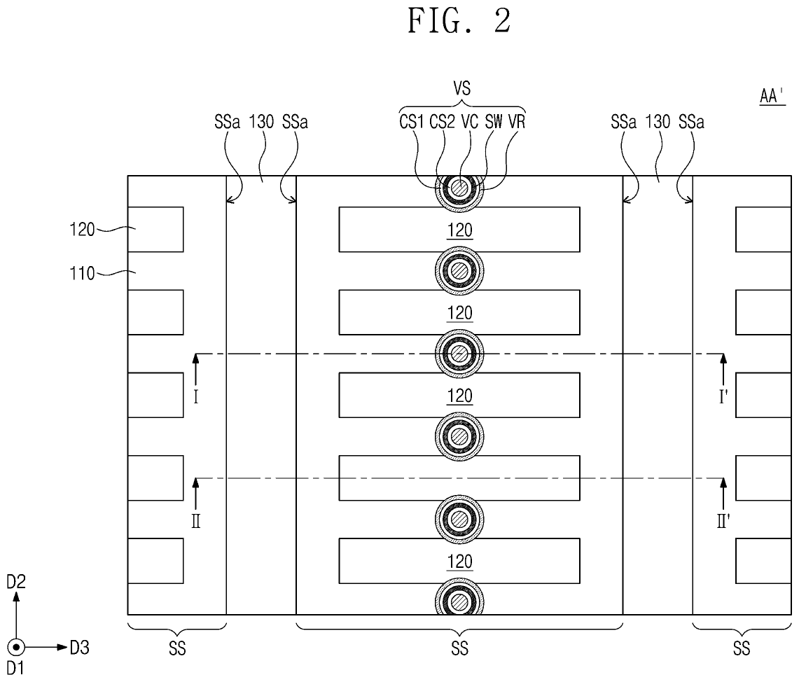

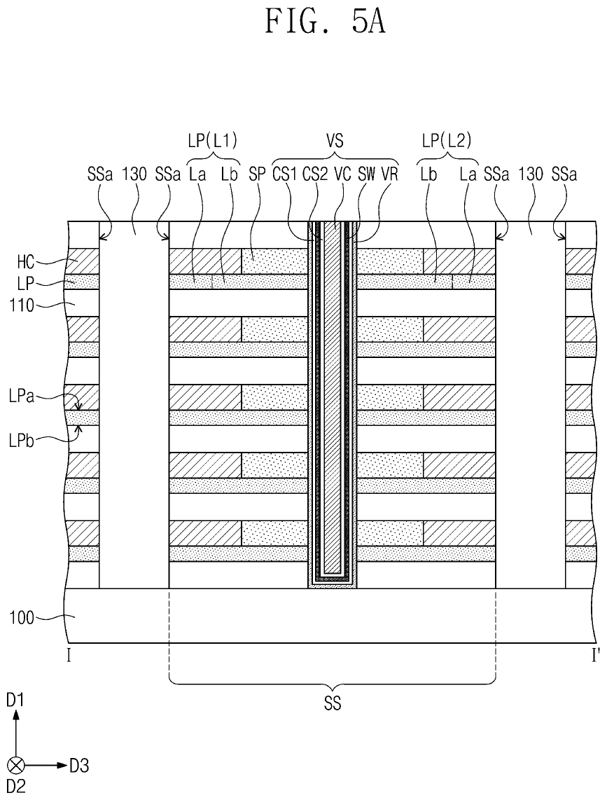

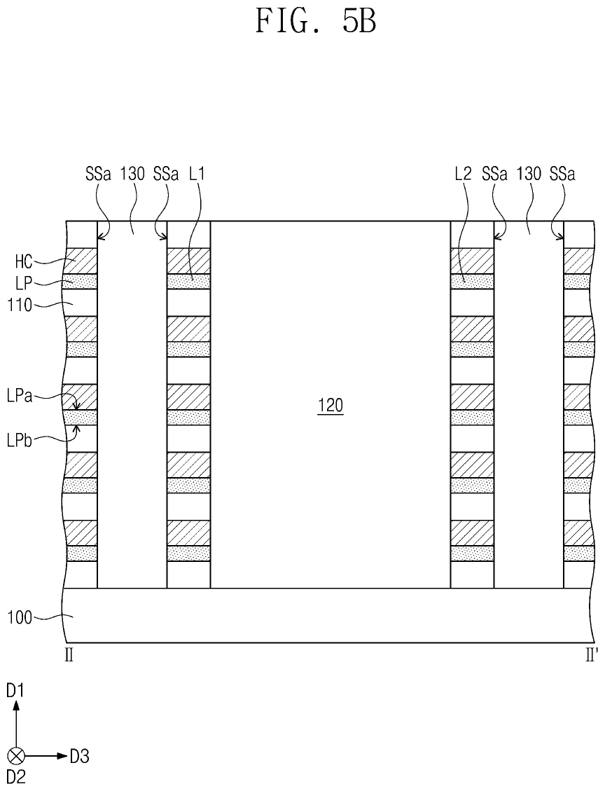

FIGS. 2 to 4 are plan views, which are respectively taken at levels AA′, BB′, and CC′ of FIG. 1 illustrating a variable resistance memory device according to an embodiment of the inventive concept. FIGS. 5A and 5B are cross-sectional views, which are respectively taken along lines I-I′ and II-II′ of FIG. 2. To the extent that an element is not described in detail, it may be assumed that the element is at least similar to a corresponding element that has been described elsewhere within the present disclosure.

Referring to FIGS. 2 to 4, 5A, and 5B, a stack SS and the vertical structure VS may be provided on a substrate 100, and here, the vertical structure VS may penetrate the stack SS in the first direction D1 perpendicular to a top surface of the substrate 100. The substrate 100 may include a semiconductor substrate. The substrate 100 may further include a thin layer that is formed on the semiconductor substrate, but the inventive concept is not necessarily limited to this example. The stack SS may extend in the second direction D2 parallel to the top surface of the substrate 100 and may be spaced apart from another stacks SS adjacent thereto in the third direction D3, which is parallel to the top surface of the substrate 100 and is non-parallel (e.g., orthogonal) to the second direction D2. Separation insulating patterns 130 may be provided on the substrate 100 and at both sides of the stack SS. The separation insulating patterns 130 may respectively cover opposite side surfaces SSa of the stack SS. The separation insulating patterns 130 may extend in the second direction D2 and may be spaced apart from each other in the third direction D3 with the stack SS interposed therebetween. Adjacent ones of the stacks SS may be spaced apart from each other with each of the separation insulating patterns 130 interposed therebetween. In an embodiment, the separation insulating patterns 130 may be formed of or may include oxide, nitride, and/or oxynitride.

The stack SS may include insulating patterns 110, the stacking patterns LP, and the horizontal conductive lines HC, which are alternately stacked in the first direction D1. As an example, a pair of the horizontal conductive lines HC may be provided on a top surface LPa of the stacking pattern LP and may be in contact with the top surface LPa of the corresponding stacking pattern LP. The pair of horizontal conductive lines HC may be in contact with the first and second sub-stacking patterns L1 and L2, respectively, of the corresponding stacking pattern LP. The pair of horizontal conductive lines HC on the corresponding stacking pattern LP may be spaced apart from each other in the third direction D3. The pair of horizontal conductive lines HC may be spaced apart from each other in the third direction D3 with a pair of the sacrificial patterns SP interposed therebetween. The pair of sacrificial patterns SP may be in contact with the top surface LPa of the corresponding stacking pattern LP and may be in contact with the first and second sub-stacking patterns L1 and L2, respectively, of the corresponding stacking pattern LP. The pair of sacrificial patterns SP on the corresponding stacking pattern LP may be spaced apart from each other in the third direction D3. Top surfaces of the pair of horizontal conductive lines HC may be located at substantially the same height as top surfaces of the pair of sacrificial patterns SP. Bottom surfaces of the pair of horizontal conductive lines HC may be located at substantially the same height as bottom surfaces of the pair of sacrificial patterns SP. A pair of the insulating patterns 110 may be respectively disposed under the bottom surface LPb of the corresponding stacking pattern LP. The pair of horizontal conductive lines HC, the pair of sacrificial patterns SP, the corresponding stacking pattern LP, and the pair of insulating patterns 110 may constitute a sub-structure, and the stack SS may include a plurality of the sub-structures which are repeatedly stacked. The insulating patterns 110 may be formed of or may include silicon oxide.

The vertical structure VS may penetrate the stack SS. As an example, the vertical structure VS may extend to the top surface of the substrate 100 in the first direction D1, but the inventive concept is not necessarily limited to this example. In an embodiment, a plurality of the vertical structures VS may be provided such that adjacent ones of the vertical structure VS are spaced apart from each other in the second direction D2. The vertical structure VS may separate the first sub-stacking pattern L1 from the second sub-stacking pattern L2, may separate the pair of sacrificial patterns SP from each other, and may separate the pair of insulating patterns 110 from each other. Each of the first sub-stacking pattern L1, the second sub-stacking pattern L2, the pair of sacrificial patterns SP, and the pair of insulating patterns 110 may be in contact with the vertical structure VS.

The vertical structure VS may include the vertical conductive line VC, the variable resistance element VR, and the selection element SW. The vertical conductive line VC may extend to the top surface of the substrate 100 in the first direction D1 to penetrate the stack SS. The variable resistance element VR may extend in the first direction D1 and may enclose the vertical conductive line VC. As an example, the variable resistance element VR may be the outermost part of the vertical structure VS and may be in contact with the stacking pattern LP. The selection element SW may be interposed between the vertical conductive line VC and the variable resistance element VR and may extend in the first direction D1.

The vertical structure VS may further include the first capping structure CS1 and the second capping structure CS2. The first capping structure CS1 may be interposed between the variable resistance element VR and the selection element SW to prevent the variable resistance element VR and the selection element SW from being in direct contact with each other. The second capping structure CS2 may be interposed between the vertical conductive line VC and the selection element SW to prevent the vertical conductive line VC and the selection element SW from being in direct contact with each other.

Each of the stacking patterns LP include the line portion La, which extends in the second direction D2, and the protruding portions Lb, which extend from the line portion La toward the vertical structures VS, respectively. Each of the protruding portions Lb of the stacking patterns LP may be in contact with the variable resistance element VR of a corresponding one of the vertical structures VS.

Each of the horizontal conductive lines HC may include the line portion Ha, which extends in the second direction D2, and the protruding portions Hb, which extend from the line portion Ha toward the vertical structures VS, respectively. Each of the protruding portions Hb of the horizontal conductive lines HC may be horizontally spaced apart from the vertical structures VS and may be in contact with a corresponding one of the sacrificial patterns SP.

The stack SS may further include gapfill insulating patterns 120 provided on the substrate 100. The gapfill insulating patterns 120 may extend from a top surface of the stack SS to the top surface of the substrate 100 in the first direction D1. The gapfill insulating patterns 120 may be provided between the first and second sub-stacking patterns L1 and L2, between the pair of horizontal conductive lines HC, and between the pair of insulating patterns 110 and may extend in the third direction D3. The gapfill insulating patterns 120 may be spaced apart from each other in the second direction D2. The vertical structure VS, the protruding portion Lb of the stacking pattern LP, the protruding portion Hb of the horizontal conductive line HC, and the sacrificial pattern SP may be interposed between adjacent ones of the gapfill insulating patterns 120. The gapfill insulating patterns 120 may be in contact with a side surface of the vertical structure VS. In an embodiment, the gapfill insulating patterns 120 may be formed of or may include oxide, nitride, and/or oxynitride.

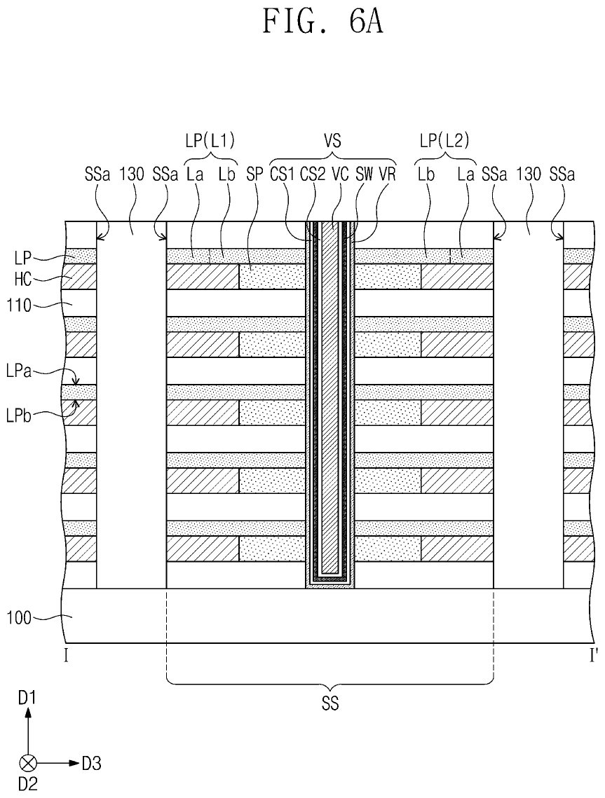

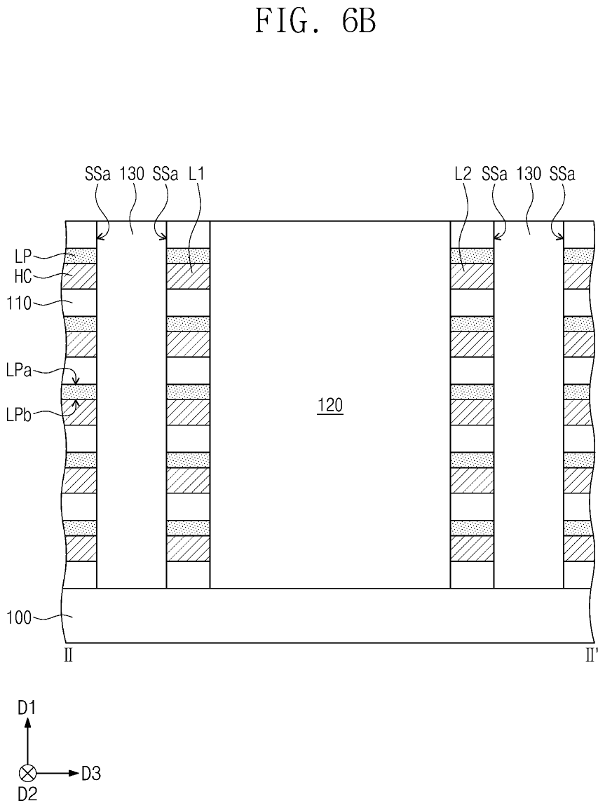

FIGS. 6A and 6B are cross-sectional views, which are respectively taken along the lines I-I′ and II-II′ of FIG. 2. To the extent that an element is not described in detail, it may be assumed that the element is at least similar to a corresponding element that has been described elsewhere within the present disclosure.

Referring to FIGS. 6A and 6B, the stack SS may include the insulating patterns 110, the stacking patterns LP, and the horizontal conductive lines HC, which are alternately stacked in the first direction D1. As an example, a pair of the horizontal conductive lines HC may be disposed under the bottom surface LPb of the stacking pattern LP and may be in contact with the bottom surface LPb of the corresponding stacking pattern LP. The pair of horizontal conductive lines HC may be in contact with the first and second sub-stacking patterns L1 and L2, respectively, of the corresponding stacking pattern LP. The pair of horizontal conductive lines HC on the corresponding stacking pattern LP may be spaced apart from each other in the third direction D3. The pair of horizontal conductive lines HC may be spaced apart from each other in the third direction D3 with the pair of sacrificial patterns SP interposed therebetween. The pair of sacrificial patterns SP may be in contact with the bottom surface LPb of the corresponding stacking pattern LP and may be in contact with the first and second sub-stacking patterns L1 and L2, respectively, of the corresponding stacking pattern LP. The pair of sacrificial patterns SP on the corresponding stacking pattern LP may be spaced apart from each other in the third direction D3. The top surfaces of the pair of horizontal conductive lines HC may be located at substantially the same height as the top surfaces of the pair of sacrificial patterns SP. The bottom surfaces of the pair of horizontal conductive lines HC may be located at substantially the same height as the bottom surfaces of the pair of sacrificial patterns SP. A pair of the insulating patterns 110 may be respectively disposed on the top surface LPa of the corresponding stacking pattern LP. The pair of horizontal conductive lines HC, the pair of sacrificial patterns SP, the corresponding stacking pattern LP, and the pair of insulating patterns 110 may constitute a sub-structure, and the stack SS may include a plurality of the sub-structures which are repeatedly stacked.

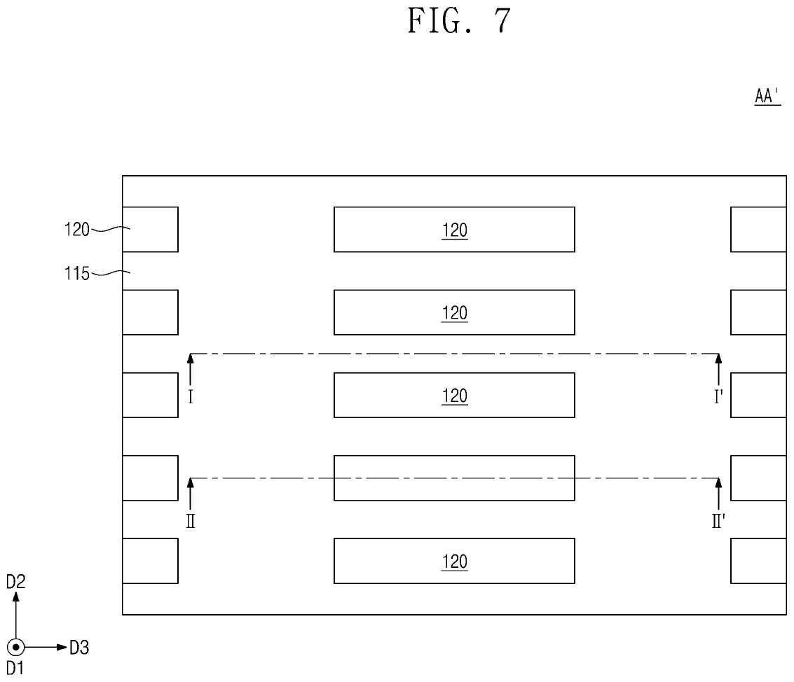

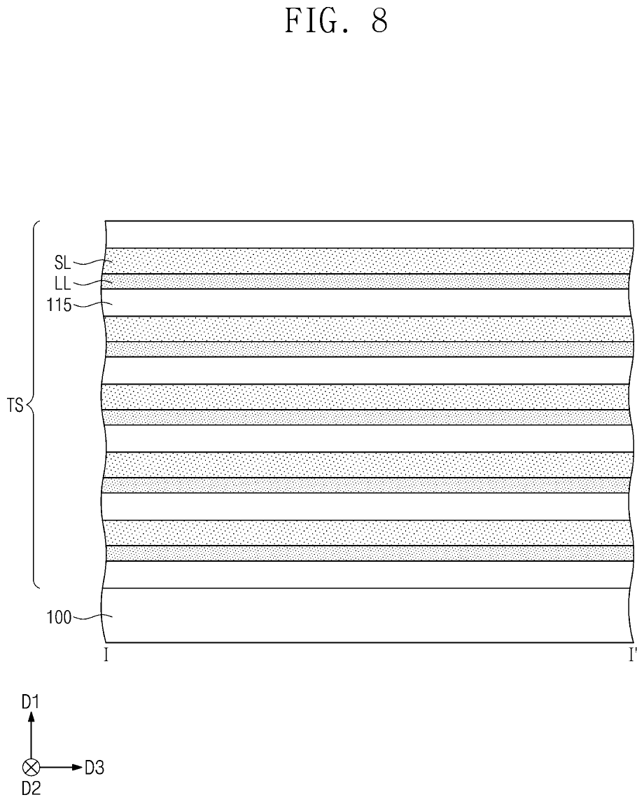

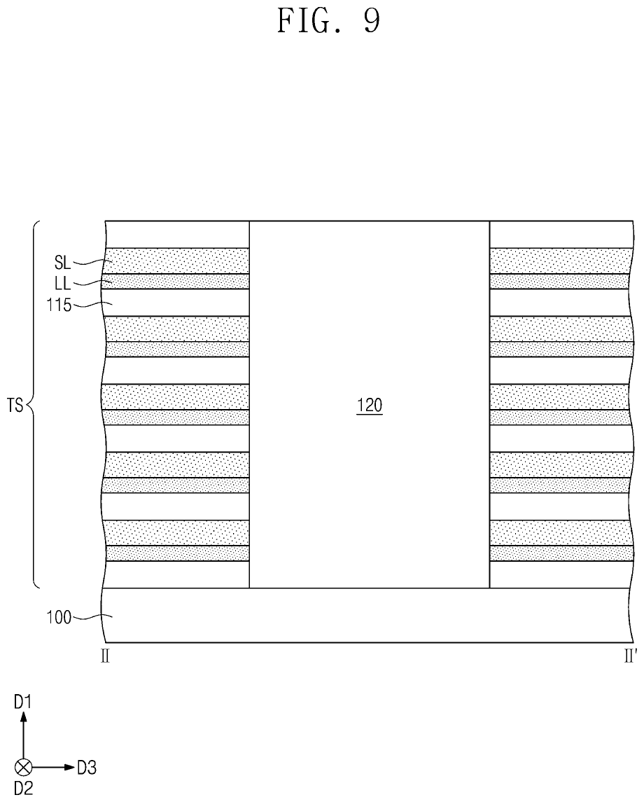

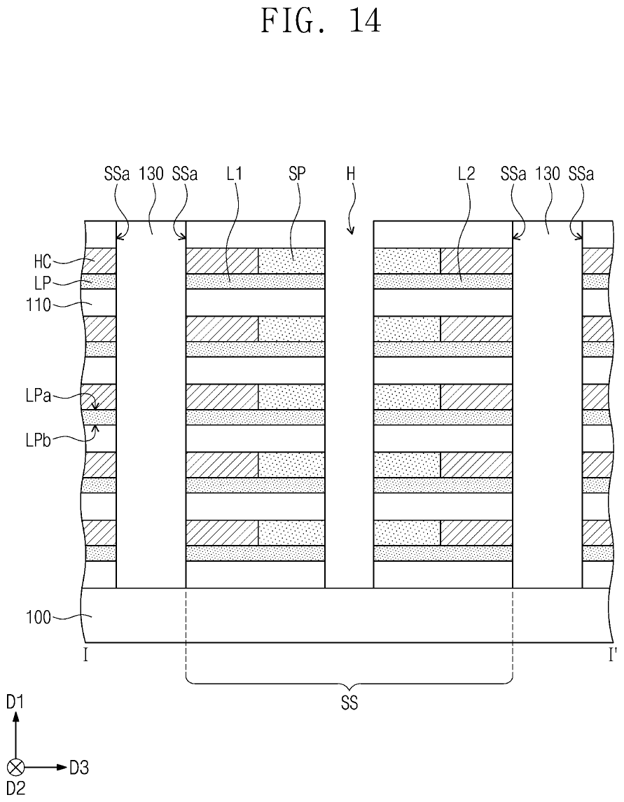

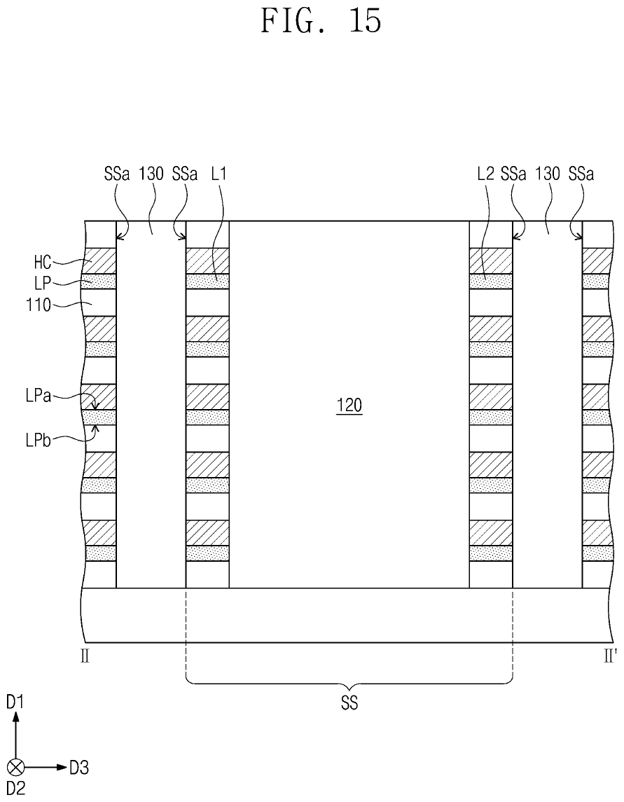

FIGS. 7 to 15 are diagrams illustrating a method of fabricating a variable resistance memory device according to an embodiment of the inventive concept. For example, FIGS. 7, 10, and 13 are plan views taken at the level AA′ of FIG. 1, FIGS. 8, 11, and 14 are cross-sectional views, which are respectively taken along lines I-I′ of FIGS. 7, 10, and 13, and FIGS. 9, 12, and 15 are cross-sectional views, which are respectively taken along lines II-II′ of FIGS. 7, 10, and 13. Hereinafter, the fabrication method of the variable resistance memory device will be described with reference to FIGS. 7 to 15. To the extent that an element is not described in detail, it may be assumed that the element is at least similar to a corresponding element that has been described elsewhere within the present disclosure.

Referring to FIGS. 7 to 9, a layered structure TS may be formed on the substrate 100. The layered structure TS may include insulating layers 115, stacking layers LL, and sacrificial layers SL, which are alternately and repeatedly stacked in the first direction D1 that is perpendicular to the top surface of the substrate 100. As an example, the uppermost one of the insulating layers 115 may be provided at the uppermost level of the layered structure TS. As an example, the insulating layers 115, the stacking layers LL, and the sacrificial layers SL may be sequentially and repeatedly stacked, as shown in FIG. 8. For example, the insulating layers 115, the sacrificial layers SL, and the stacking layers LL may be sequentially and repeatedly stacked. The description that follows will refer to an example of FIG. 8, in which the insulating layers 115, the stacking layers LL, and the sacrificial layers SL are sequentially stacked, for convenience in description. However, the inventive concept is not necessarily limited to this example, and except for structural differences caused by a difference in the stacking order, technical features in the fabrication method may be substantially the same.

The insulating layers 115 may be formed of or may include silicon oxide. The sacrificial layers SL may be formed of or may include silicon nitride. The stacking layers LL may be formed of or may include one or more two-dimensional materials. As an example, the stacking layers LL may be a single layer including a two-dimensional material. For example, the stacking layers LL may be formed of or may include one or more two-dimensional materials and may be composed of a plurality of layers. As an example, the two-dimensional material of the stacking layers LL may include graphene and/or transition metal dichalcogenides (TMD).

The gapfill insulating patterns 120 may penetrate the layered structure TS in the first direction D1. The gapfill insulating patterns 120 may penetrate the insulating layers 115, the stacking layers LL, and the sacrificial layers SL in the first direction D1. The gapfill insulating patterns 120 may be spaced apart from each other in the second direction D2, which is parallel to the top surface of the substrate 100, and may extend in the third direction D3, which is parallel to the top surface of the substrate 100 and is non-parallel (e.g., orthogonal) to the second direction D2. Each of the gapfill insulating patterns 120 may extend in the first direction D1 and may be in contact with the top surface of the substrate 100. In an embodiment, the formation of the gapfill insulating patterns 120 may include forming penetration holes to penetrate the layered structure TS, forming an insulating gapfill layer filling the penetration holes and covering the layered structure TS, and planarizing the insulating gapfill layer exposing a top surface of the layered structure TS. In an embodiment, the formation of the penetration holes may include forming a mask pattern on the layered structure TS to define regions, in which the gapfill insulating patterns 120 will be formed, and etching the layered structure TS using the mask pattern as an etch mask. The penetration holes may be spaced apart from each other in the second direction D2, and each of the penetration holes may be a line-shaped empty region that extends in the third direction D3. Each of the penetration holes may expose the top surface of the substrate 100. As a result of the planarization of the insulating gapfill layer, the gapfill insulating patterns 120 may be locally formed in the penetration holes. In an embodiment, the gapfill insulating patterns 120 may be formed of or may include oxide, nitride, and/or oxynitride.

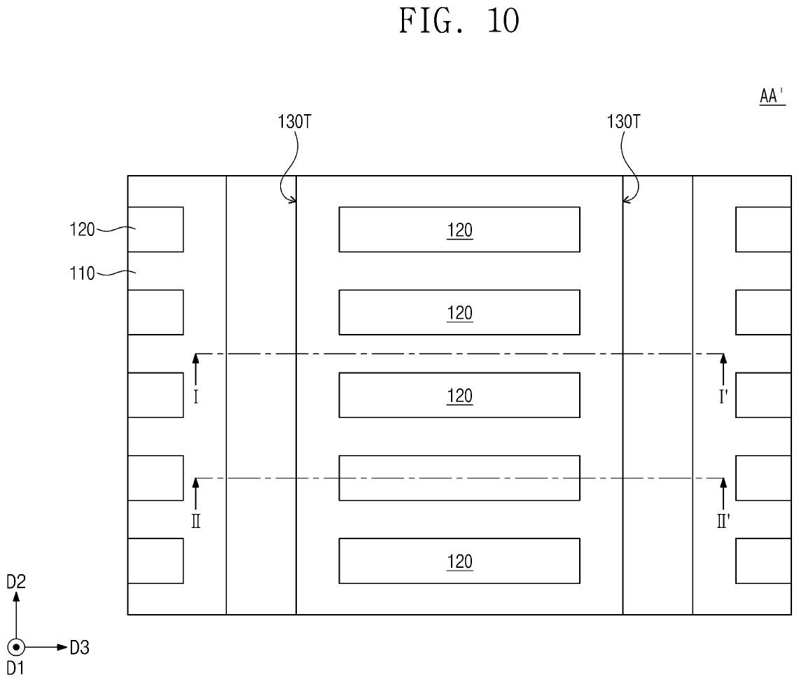

Referring to FIGS. 10 to 12, a pair of trenches 130T may penetrate the layered structure TS in the first direction D1. The pair of trenches 130T may extend in the second direction D2 and may be spaced apart from each other in the third direction D3. The pair of trenches 130T may be spaced apart from each other in the third direction D3 with the gapfill insulating patterns 120 interposed therebetween. Each of the pair of trenches 130T may expose side surfaces of the insulating layers 115, the stacking layers LL, and the sacrificial layers SL of the layered structure TS and the top surface of the substrate 100. In an embodiment, the formation of the trenches 130T may include a mask pattern on the layered structure TS to define regions, in which the trenches 130T will be formed, and etching the layered structure TS using the mask pattern as an etch mask. The insulating layers 115 and the stacking layers LL may be respectively divided into the insulating patterns 110 and the stacking patterns LP by the pair of trenches 130T.

The side surfaces of the sacrificial layers SL, which are exposed by each of the trenches 130T, may be recessed. Accordingly, recess regions RE may be formed between the insulating patterns 110, which are spaced apart from each other in the first direction D1. In an embodiment, the formation of the recess regions RE may include performing an etching process, which has an etch selectivity with respect to the insulating patterns 110, the gapfill insulating patterns 120, the stacking patterns LP and the substrate 100, to etch the exposed side portions of the sacrificial layers SL. The recess regions RE may be horizontally extended in each of the trenches 130T. The recess regions RE may extend in the third direction D3 and may be spaced apart from each other in the first direction D1. Each of the recess regions RE may be formed between a pair of the insulating patterns 110, which are adjacent to each other in the first direction D1.

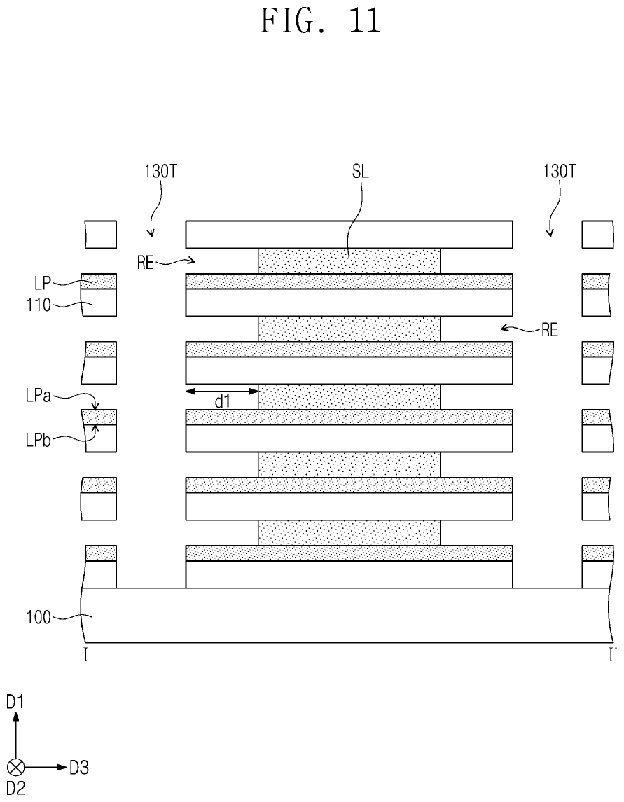

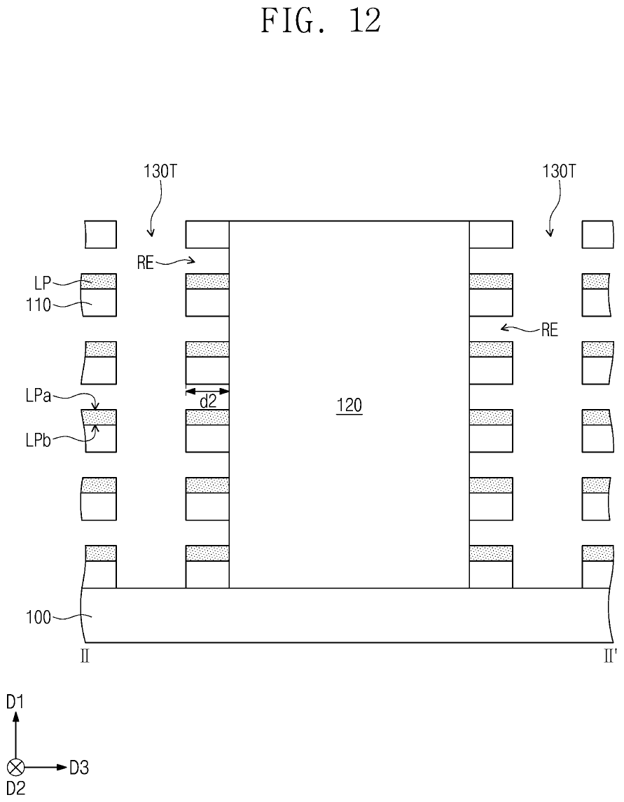

As shown in FIG. 11, the recess region RE may have a first portion that extends from side surfaces of the insulating patterns 110 in the third direction D3 exposing the side surfaces of the sacrificial layers SL. When measured in the third direction D3, the first portion of the recess region RE may be a first width d1, when is a distance from the side surfaces of the insulating patterns 110 to the side surfaces of the sacrificial layers SL. As shown in FIG. 12, the recess regions RE may include a second portion that extends from the side surfaces of the insulating patterns 110 in the third direction D3 exposing side surfaces of the gapfill insulating patterns 120. When measured in the third direction D3, the second portion of the recess regions RE may have a second width d2, which is a distance from the side surfaces of the insulating patterns 110 to the side surfaces of the gapfill insulating patterns 120. The first width d1 may be larger than the second width d2.

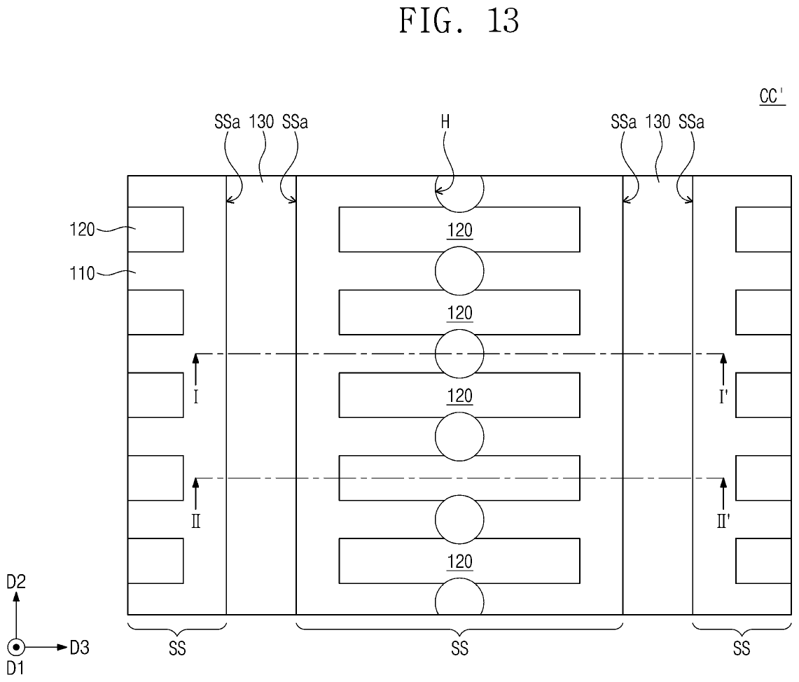

Referring to FIGS. 13 to 15, the horizontal conductive lines HC may be formed in the recess regions RE, respectively. In an embodiment, the formation of the horizontal conductive lines HC may include forming a first conductive layer filling the recess regions RE and filling at least a portion of the trenches 130T and removing the first conductive layer from the trenches 130T. The first conductive layer may be formed of or may include a metallic material (e.g., copper, tungsten, or aluminum) and/or metal nitride materials (e.g., tantalum nitride, titanium nitride, or tungsten nitride). The removal of the first conductive layer may include etching the first conductive layer exposing a top surface of the uppermost insulating pattern 110 and an inner surface of each of the trenches 130T. As a result of the etching of the first conductive layer, the horizontal conductive lines HC may be locally formed in the recess regions RE. Each of the horizontal conductive lines HC may extend in the third direction D3 and may be in contact with side surfaces of the gapfill insulating patterns 120 and side surfaces of the sacrificial layers SL between the gapfill insulating patterns 120.

The separation insulating patterns 130 may be formed in the trenches 130T, respectively. In an embodiment, the formation of the separation insulating patterns 130 may include forming a separation insulating layer filling the trenches 130T and planarizing the separation insulating layer exposing the top surface of the uppermost insulating pattern 110. As a result of the planarization process, the separation insulating patterns 130 may be locally formed in the trenches 130T. The separation insulating patterns 130 may extend in the second direction D2 and may be spaced apart from each other the third direction D3 with the horizontal conductive lines HC interposed therebetween. In an embodiment, the separation insulating patterns 130 may be formed of or may include oxide, nitride, and/or oxynitride.

Vertical holes H may penetrate the insulating patterns 110, the stacking patterns LP, and the sacrificial layers SL. The vertical holes H between the separation insulating patterns 130 may be spaced apart from each other in the second direction D2. The vertical holes H and the gapfill insulating patterns 120 may be alternately arranged in the second direction D2. Each of the vertical holes H may expose side surfaces of the insulating patterns 110, side surfaces of the stacking patterns LP, side surfaces of the sacrificial layers SL, and the top surface of the substrate 100. As a result of the formation of the vertical holes H, each of the sacrificial layers SL may be divided into a pair of the sacrificial patterns SP. As a result of the formation of the vertical holes H, each of the insulating patterns 110 may include two patterns that are separated from each other. Each of the stacking patterns LP may be divided into the first and second sub-stacking patterns L1 and L2, which are respectively disposed at both sides of the vertical holes H. The insulating patterns 110, the horizontal conductive lines HC, the stacking patterns LP, and the sacrificial patterns SP may constitute the stack SS.

In an embodiment, the formation of the vertical holes H may include forming a mask pattern on the uppermost insulating pattern 110 to define regions, in which the vertical holes H will be formed, and etching the insulating patterns 110, the stacking patterns LP, and the sacrificial layers SL using the mask pattern as an etch mask.

Referring back to FIGS. 2, 5A, and 5B, the vertical structures VS may fill the vertical holes H. The vertical structures VS may extend in the first direction D1 and may be spaced apart from each other in the second direction D2 between the separation insulating patterns 130. The vertical structures VS and the gapfill insulating patterns 120 may be alternately arranged in the second direction D2. Each of the vertical structures VS may be in contact with the side surfaces of the insulating patterns 110, the stacking patterns LP, and the sacrificial patterns SP.

As an example, each of the vertical structures VS may include the vertical conductive line VC, the variable resistance element VR, and the selection element SW. The formation of the vertical structures VS may include forming the variable resistance element VR, forming the selection element SW, and forming the vertical conductive line VC.

The formation of the variable resistance element VR may include forming a variable resistance layer covering an inner surface of each of the vertical holes H and a top surface of the uppermost insulating pattern 110 and etching the variable resistance layer exposing the top surface of the uppermost insulating pattern 110.

The formation of the selection element SW may include forming a selection element layer covering an inner surface of the variable resistance element VR in the vertical hole H and the top surface of the uppermost insulating pattern 110 and etching the selection element layer exposing the top surface of the uppermost insulating pattern 110.

The formation of the vertical conductive line VC may include forming a second conductive layer filling remaining portions of the vertical holes H and covering the top surface of the uppermost insulating pattern 110 and exposing the second conductive layer exposing the top surface of the uppermost insulating pattern 110.

For example, the formation of the vertical structure VS may include forming a variable resistance layer covering the inner surface of each of the vertical holes H and the top surface of the uppermost insulating pattern 110, forming a selection element layer covering an inner surface of the variable resistance layer in the vertical hole H and the top surface of the uppermost insulating pattern 110, forming a second conductive layer filling remaining portions of the vertical holes H and covering the top surface of the uppermost insulating pattern 110, and etching the second conductive layer, the selection element layer, and the variable resistance layer exposing the top surface of the uppermost insulating pattern 110.

The formation of the vertical structure may further include forming the first capping structure CS1 and the second capping structure CS2. The formation of the first capping structure CS1 may include forming a first capping layer covering an inner surface of the variable resistance element VR in the vertical hole H and the top surface of the uppermost insulating pattern 110 and etching the first capping layer exposing the top surface of the uppermost insulating pattern 110. The formation of the first capping structure CS1 may include forming a second capping layer covering an inner surface of the selection element SW in the vertical hole H and the top surface of the uppermost insulating pattern 110 and etching the second capping layer exposing the top surface of the uppermost insulating pattern 110.

However, the inventive concept is not necessarily limited to this example, and an order of forming and etching layers in the vertical structure VS may be variously changed or modified by a skilled person in the art.

Power required for writing data in the variable resistance memory device may be determined by a contact area between the variable resistance element VR and the electrode (i.e., the stacking pattern LP). In the case where the variable resistance element VR or the electrode is formed in each of the recess regions RE, the variable resistance element VR or the electrode may be non-uniformly deposited. In this case, there may be a difficulty in controlling the contact area between the variable resistance element VR and the electrode and controlling the power consumption property of the variable resistance memory device.

According to an embodiment of the inventive concept, the variable resistance element VR may be formed in a shape extending in the first direction D1 and may be uniformly deposited. The stacking pattern LP (i.e., the electrode) may be formed on the insulating layer 115 or the sacrificial layer SL, which is provided to have a flat shape. For example, the variable resistance element VR and the stacking pattern LP may be uniformly formed throughout the entire region. Accordingly, the contact area may be controlled by adjusting the number or thickness of the stacking patterns LP, and as a result, it may be possible to control power consumption in the variable resistance memory device.

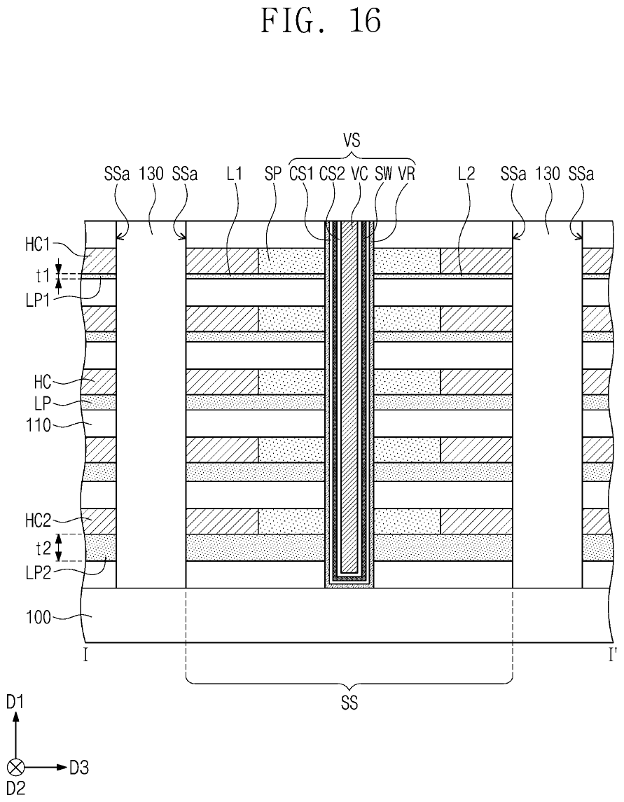

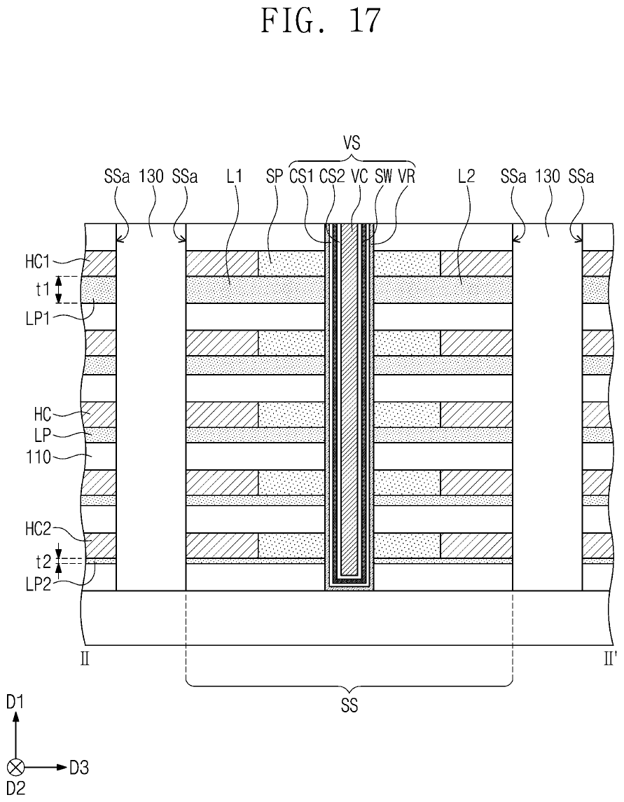

FIGS. 16 and 17 are cross-sectional views, each of which is taken along the line I-I′ of FIG. 2 illustrating a variable resistance memory device according to an embodiment of the inventive concept. To the extent that an element is not described in detail, it may be assumed that the element is at least similar to a corresponding element that has been described elsewhere within the present disclosure.

Referring to FIGS. 16 and 17, the stacking patterns LP may include a first stacking pattern LP1 and a second stacking pattern LP2. The first stacking pattern LP1 and the second stacking pattern LP2 may be located at different heights in the first direction D1 and may be spaced apart from each other in the first direction D1. The first stacking pattern LP1 may be located at a height higher than the second stacking pattern LP2.

The horizontal conductive lines HC may be located at different heights in the first direction D1 and may include a first horizontal conductive line HC1 and a second horizontal conductive line HC2, which are spaced apart from each other in the first direction D1. The first horizontal conductive line HC1 may be electrically connected to the first stacking pattern LP1, and the second horizontal conductive line HC2 may be electrically connected to the second stacking pattern LP2.

When measured in the first direction D1, the first stacking pattern LP1 may have a first thickness t1, and the second stacking pattern LP2 may have a second thickness t2. The first thickness t1 and the second thickness t2 may be different from each other. As an example, the first thickness t1 may be smaller than the second thickness t2, as previously shown in FIG. 16. For example, the first thickness t1 may be larger than the second thickness t2, as previously shown in FIG. 17.

A composition of the variable resistance element VR may vary depending on a height in the first direction D1. Power required for changing a degree of crystallization of the variable resistance element VR depends on the height. According to an embodiment of the inventive concept, the thicknesses of the stacking patterns LP may vary depending on a position of each of the stacking patterns LP, and thus, different power consumption may be provided according to the position of each of the stacking patterns LP. As a result, it may be possible to control power consumption in the variable resistance memory device.

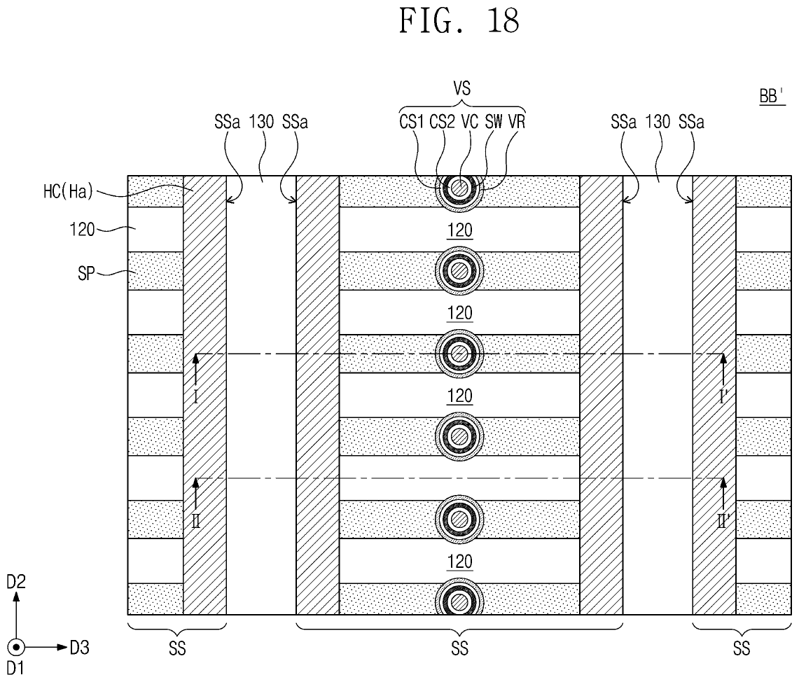

FIG. 18 is a plan view, which is taken at the level BB′ of FIG. 1 illustrating a variable resistance memory device according to an embodiment of the inventive concept. To the extent that an element is not described in detail, it may be assumed that the element is at least similar to a corresponding element that has been described elsewhere within the present disclosure.

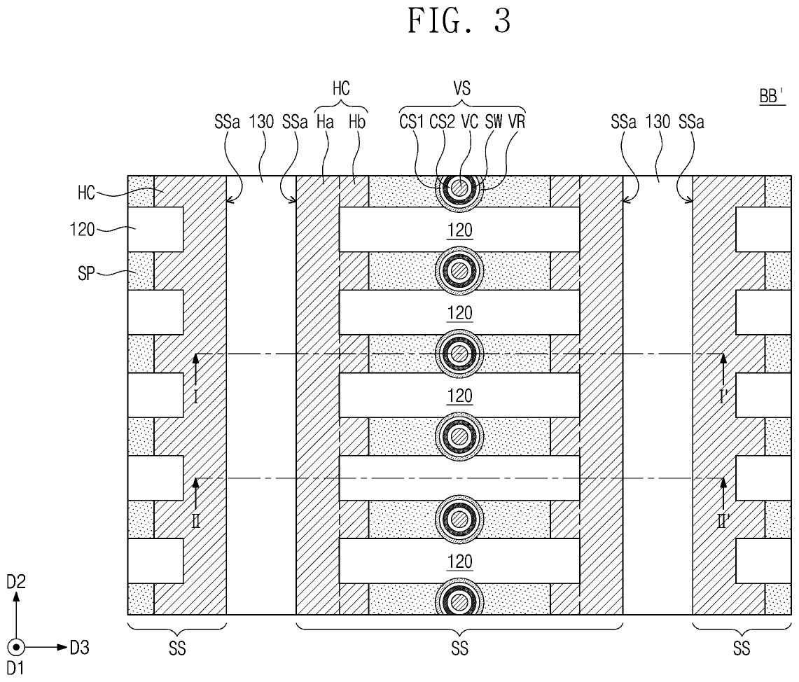

Referring to FIG. 18, in a plan view, the horizontal conductive line HC may be linearly extended in the second direction D2. For example, the horizontal conductive line HC may be composed of the line portion Ha, without the protruding portion Hb of FIG. 3. The horizontal conductive line HC may be in contact with side surfaces of the gapfill insulating patterns 120 and side surfaces of the sacrificial patterns SP.

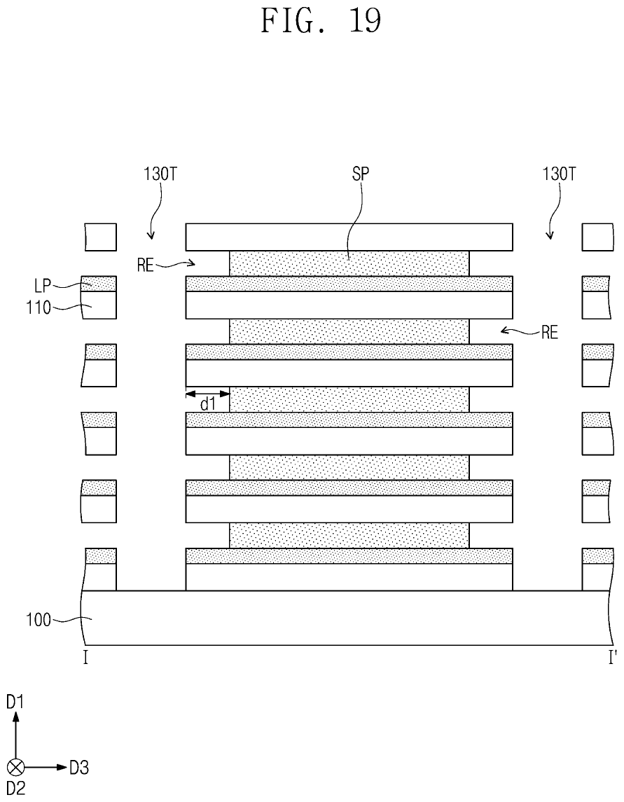

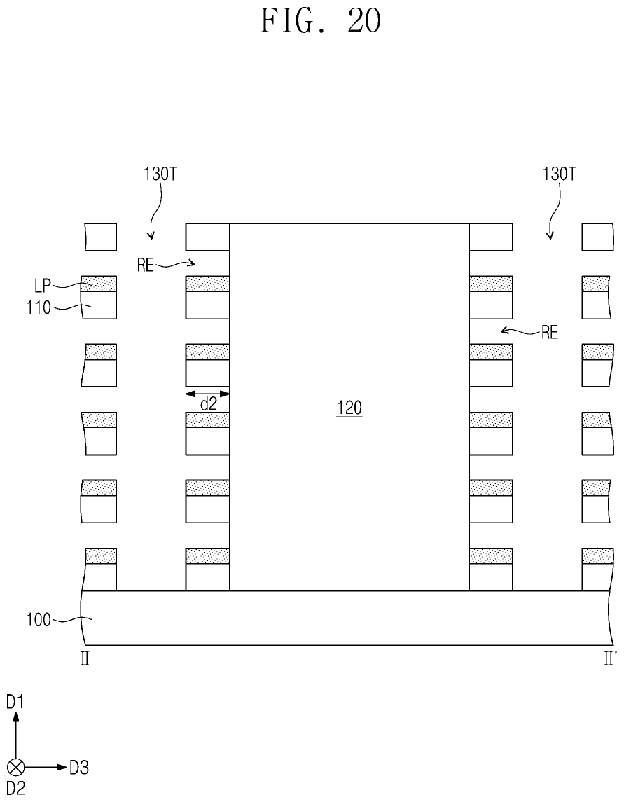

FIGS. 19 and 20 are cross-sectional views, which are respectively taken along lines I-I′ and II-II′ of FIG. 18 illustrating a method of fabricating the variable resistance memory device of FIG. 18. Hereinafter, the method of fabricating the variable resistance memory device of FIG. 18 will be described with reference to FIGS. 19 and 20. To the extent that an element is not described in detail, it may be assumed that the element is at least similar to a corresponding element that has been described elsewhere within the present disclosure.

Referring to FIGS. 19 and 20, the side surfaces of the sacrificial layers SL exposed by each of the trenches 130T may be recessed to form the recess regions RE, after the fabrication process described with reference to FIGS. 8 to 10.

As shown in FIG. 19, the recess region RE may include a first portion that extends from the side surfaces of the insulating patterns 110 in the third direction D3 exposing the side surfaces of the sacrificial layers SL. When measured in the third direction D3, the first portion of the recess region RE may be a first width d1, when is a distance from the side surfaces of the insulating patterns 110 to the side surfaces of the sacrificial layers SL. As shown in FIG. 20, the recess region RE may have a second portion that extends from the side surfaces of the insulating patterns 110 in the third direction D3 exposing the side surfaces of the gapfill insulating patterns 120. When measured in the third direction D3, the second portion of the recess regions RE may have a second width d2, which is a distance from the side surfaces of the insulating patterns 110 to the side surfaces of the gapfill insulating patterns 120. The first width d1 may be substantially equal to the second width d2. Thereafter, the variable resistance memory device of FIG. 18 may be formed through the fabrication process described with reference to FIGS. 13 to 15, 2, 5A, and 5B.

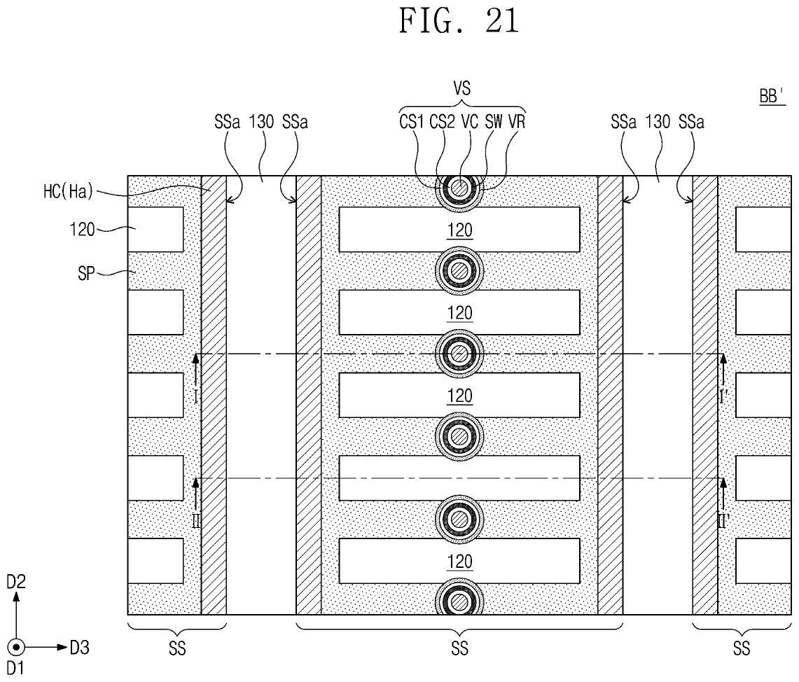

FIG. 21 is a plan view, which is taken at the level BB′ of FIG. 1 illustrating a variable resistance memory device according to an embodiment of the inventive concept. To the extent that an element is not described in detail, it may be assumed that the element is at least similar to a corresponding element that has been described elsewhere within the present disclosure.

Referring to FIG. 21, in a plan view, the horizontal conductive line HC may be linearly extended in the second direction D2. For example, the horizontal conductive line HC may be composed of the line portion Ha, without the protruding portion Hb of FIG. 3. The horizontal conductive line HC may be in contact with side surfaces of the sacrificial patterns SP and may be horizontally spaced apart from side surfaces of the gapfill insulating patterns 120.

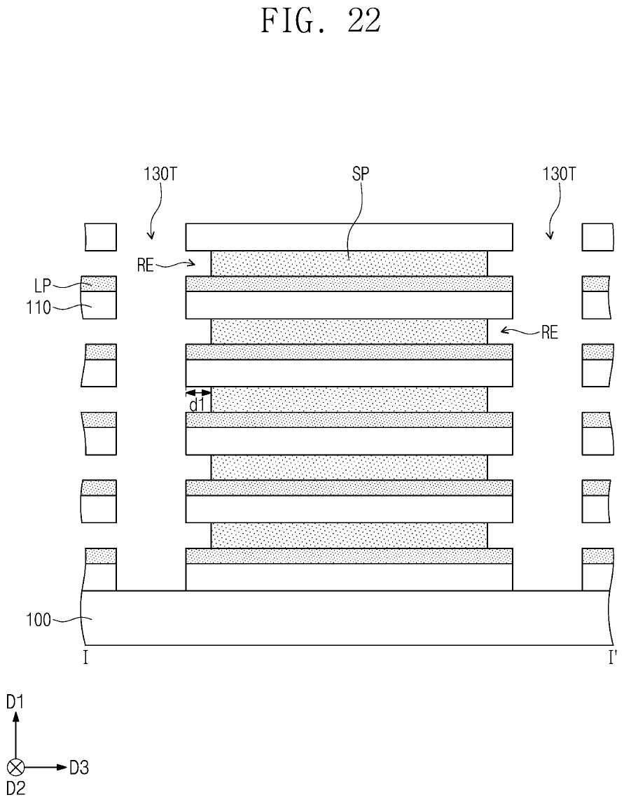

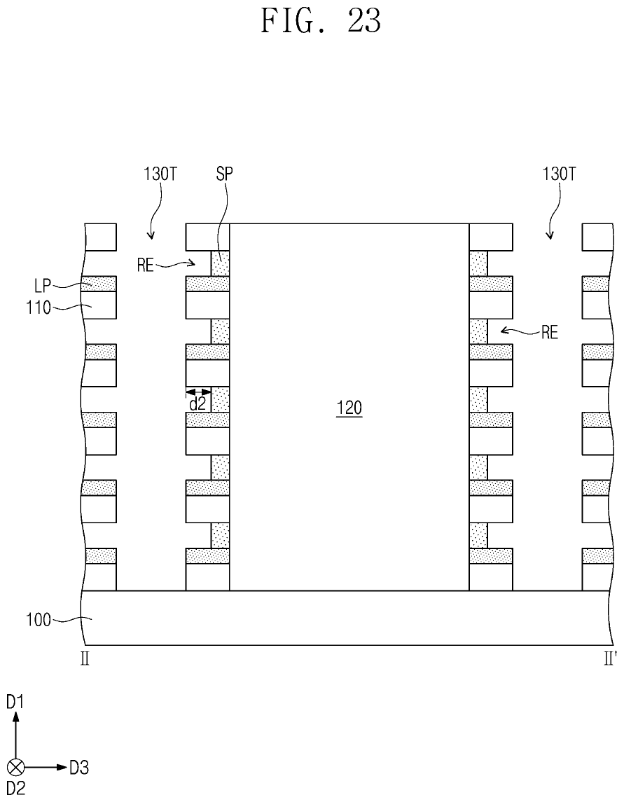

FIGS. 22 and 23 are cross-sectional views, which are respectively taken along lines I-I′ and II-II′ of FIG. 21 illustrating a method of fabricating the variable resistance memory device of FIG. 21. Hereinafter, the method of fabricating the variable resistance memory device of FIG. 21 will be described with reference to FIGS. 22 and 23. To the extent that an element is not described in detail, it may be assumed that the element is at least similar to a corresponding element that has been described elsewhere within the present disclosure.

Referring to FIGS. 22 and 23, the side surfaces of the sacrificial layers SL exposed by each of the trenches 130T may be recessed to form the recess regions RE, after the fabrication process described with reference to FIGS. 8 to 10.

The recess regions RE may expose side surfaces of the sacrificial layers SL. Side surfaces of the gapfill insulating patterns 120 may be covered with the sacrificial layers SL and thus might not be exposed to the recess regions RE. Accordingly, widths d1 and d2 of the recess regions RE measured in the third direction D3 may be substantially constant through the entire region. Thereafter, the fabrication process described with reference to FIGS. 13 to 15, 2, 5A, and 5B may be further performed to fabricate the variable resistance memory device of FIG. 21.

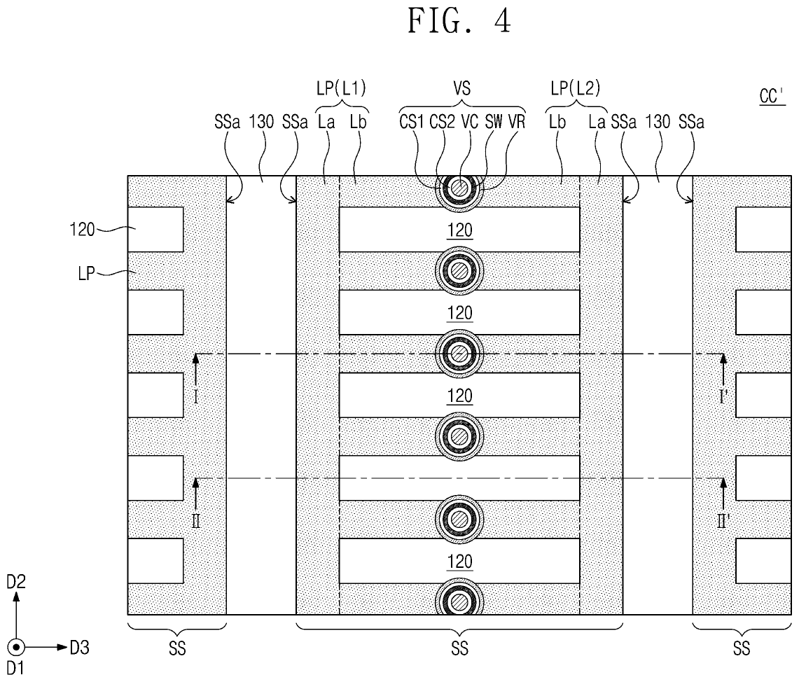

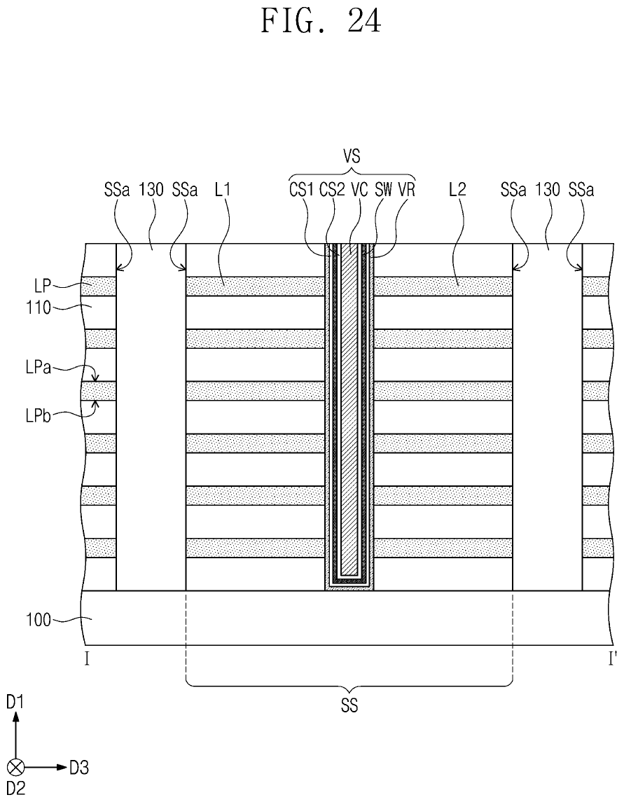

FIG. 24 is a cross-sectional view, which is taken along the lines I-I′ of FIGS. 2 and 4 illustrating a variable resistance memory device according to an embodiment of the inventive concept. To the extent that an element is not described in detail, it may be assumed that the element is at least similar to a corresponding element that has been described elsewhere within the present disclosure.

Referring to FIGS. 2, 4, and 24, the stack SS may be provided on the substrate 100, and in an embodiment, the stack SS may include the stacking patterns LP and the insulating patterns 110, which are alternately stacked on the substrate 100. The vertical structures VS may penetrate the stack SS in the first direction D1. Each of the stacking patterns LP may include the first and second sub-stacking patterns L1 and L2, which are spaced apart from each other with the vertical structures VS interposed therebetween. Each of the first and second sub-stacking patterns L1 and L2 may extend in the second direction D2. A pair of the insulating patterns 110 may be disposed on the first and second sub-stacking patterns L1 and L2.

The stacking patterns LP may be formed of or may include one or more two-dimensional materials. Each of the stacking patterns LP may be a single or multiple layer including a two-dimensional material. As an example, the two-dimensional material of the stacking pattern LP may include graphene and/or transition metal dichalcogenides (TMD). The insulating patterns 110 may be formed of or may include silicon oxide.

The separation insulating patterns 130 may be provided on the substrate 100 and at both sides of the stack SS. The separation insulating patterns 130 may extend in the second direction D2 and may be spaced apart from each other in the third direction D3 with the stack SS interposed therebetween. In an embodiment, the separation insulating patterns 130 may be formed of or may include oxide, nitride, and/or oxynitride.

The vertical structures VS may extend in the first direction D1 and may penetrate the stack SS. The vertical structures VS may separate the first sub-stacking pattern L1 from the second sub-stacking pattern L2 and may separate the pair of insulating patterns 110 from each other. The first and second sub-stacking patterns L1 and L2 and the pair of insulating patterns 110 may be in contact with the vertical structures VS.

Each of the vertical structures VS may include the vertical conductive line VC, the variable resistance element VR, and the selection element SW. The vertical conductive line VC may penetrate the stacking pattern LP. The variable resistance element VR may enclose the vertical conductive line VC. The selection element SW may be interposed between the vertical conductive line VC and the variable resistance element VR. Each of the vertical conductive line VC, the variable resistance element VR, and the selection element SW may extend in the first direction D1.

The vertical conductive line VC may be formed of or may include a metallic material (e.g., copper, tungsten, or aluminum) and/or metal nitride materials (e.g., tantalum nitride, titanium nitride, or tungsten nitride). The selection element SW may be a diode or may be a device having a non-linear (e.g., S-shaped) I-V curve, based on a threshold switching phenomenon. As an example, the selection element SW may be an ovonic threshold switch (OTS) device having a bi-directional property. The variable resistance element VR may include a material, which has a variable resistance property, and this may make it possible to use the variable resistance element VR as a data-storing element. In an embodiment, the variable resistance element VR may include a material whose phase can be changed to one of crystalline and amorphous structures, depending on its temperature. Each of the vertical structures VS may further include the first capping structure CS1 and the second capping structure CS2. The first capping structure CS1 may be interposed between the variable resistance element VR and the selection element SW, and the second capping structure CS2 may be interposed between the vertical conductive line VC and the selection element SW.

The stack SS may further include the gapfill insulating patterns 120 provided on the substrate 100. The gapfill insulating patterns 120 may extend from the top surface of the stack SS to the top surface of the substrate 100 in the first direction D1. The gapfill insulating patterns 120 may be provided between the first and second sub-stacking patterns L1 and L2 and between the pair of insulating patterns 110 and may extend in the third direction D3. The gapfill insulating patterns 120 and the vertical structure VS may be alternately arranged in the second direction D2. In an embodiment, the gapfill insulating patterns 120 may be formed of or may include oxide, nitride, and/or oxynitride.

The top and bottom surfaces LPa and LPb of the stacking patterns LP may be in contact with the insulating patterns 110. For example, the first and second sub-stacking patterns L1 and L2 may have top surfaces which are in contact with the bottom surfaces of a pair of the insulating patterns 110 thereon. The first and second sub-stacking patterns L1 and L2 may have bottom surfaces which are in contact with the top surfaces of another pair of the insulating patterns 110 thereunder. The stacking patterns LP and the insulating patterns 110 may be vertically overlapped with each other. The stacking patterns LP and the insulating patterns 110 may extend from the separation insulating patterns 130 to the vertical structures VS in the third direction D3.

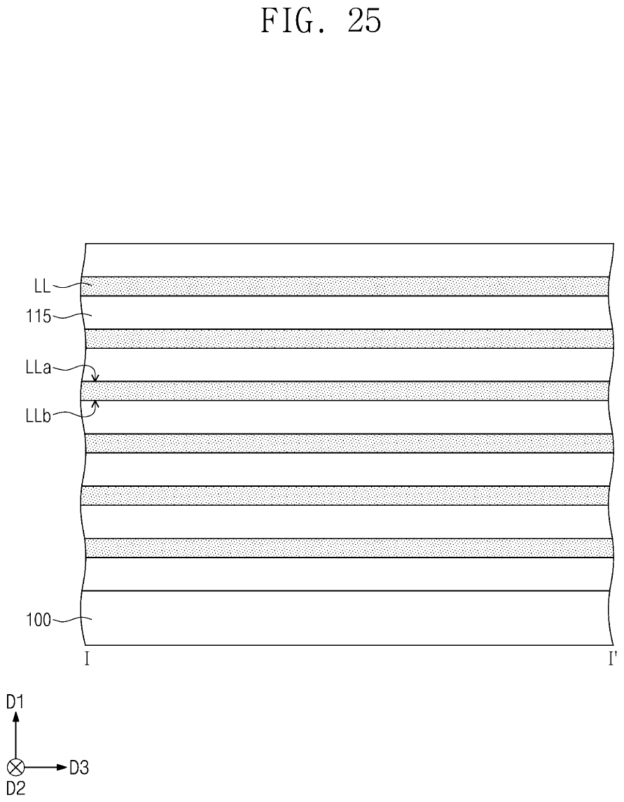

FIGS. 25 to 27 are cross-sectional views illustrating a method of fabricating the variable resistance memory device of FIG. 24. Hereinafter, the method of fabricating the variable resistance memory device of FIG. 24 will be described with reference to FIGS. 25 to 27. To the extent that an element is not described in detail, it may be assumed that the element is at least similar to a corresponding element that has been described elsewhere within the present disclosure.

Referring to FIG. 25, the stacking layers LL and the insulating layers 115 may be alternately stacked on the substrate 100. As an example, the uppermost one of the insulating layers 115 may be placed at a level higher than the uppermost one of the stacking layers LL. The insulating layers 115 may be formed of or may include silicon oxide. The stacking layers LL may be formed of or may include lone or more two-dimensional materials. The gapfill insulating patterns 120 may penetrate the stacking layers LL and the insulating layers 115 in the first direction D1. The stacking layers LL may have top surfaces LLa and bottom surfaces LLb that are in contact with the insulating layers 115.

In an embodiment, the stacking layers LL may be formed of or may include one or more two-dimensional materials. The insulating layers 115 may be formed of or may include silicon oxide.

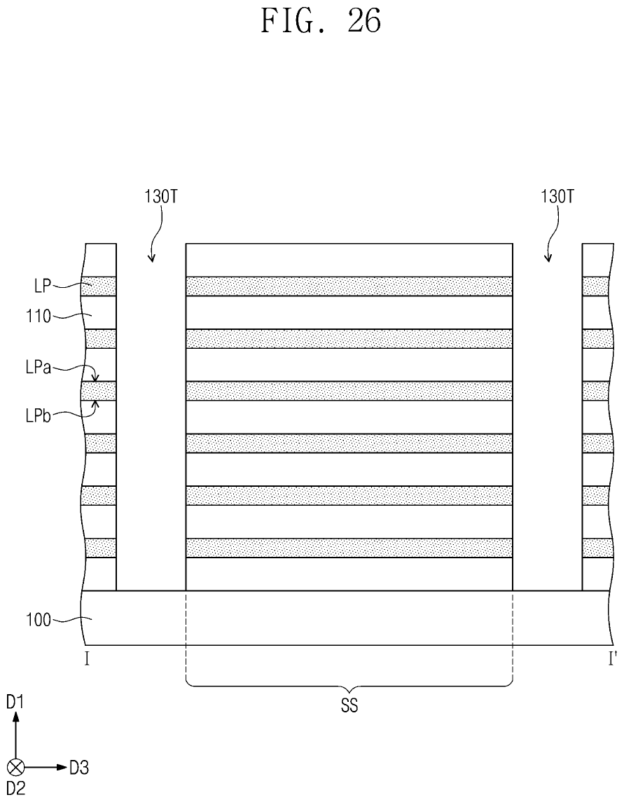

Referring to FIG. 26, a pair of the trenches 130T may penetrate the stacking layers LL and the insulating layers 115 in the first direction D1. The pair of trenches 130T may extend in the second direction D2 and may be spaced apart from each other in the third direction D3. Each of the trenches 130T may expose side surfaces of the insulating layers 115, side surfaces of the stacking layers LL, and the top surface of the substrate 100. The insulating layers 115 and the stacking layers LL may be respectively divided into the insulating patterns 110 and the stacking patterns LP by the pair of trenches 130T.

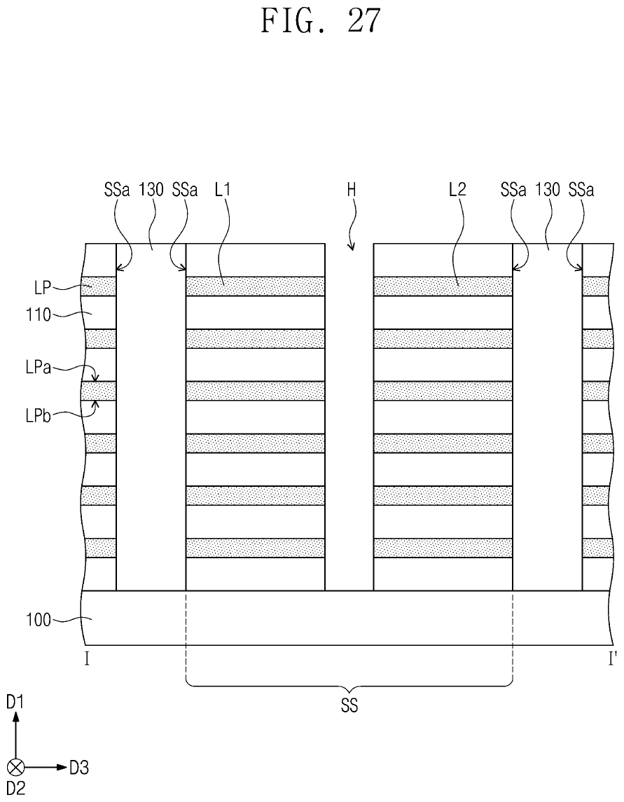

Referring to FIG. 27, the separation insulating patterns 130 may be formed in the trenches 130T, respectively. In an embodiment, the separation insulating patterns 130 may be formed of or may include oxide, nitride, and/or oxynitride.

The vertical holes H may penetrate the insulating patterns 110 and the stacking patterns LP. The vertical holes H between the separation insulating patterns 130 may be spaced apart from each other in the second direction D2. Each of the vertical holes H may expose side surfaces of the insulating patterns 110, side surfaces of the stacking patterns LP, and the top surface of the substrate 100. As a result of the formation of the vertical holes H, each of the insulating patterns 110 may include two patterns that are separated from each other. Each of the stacking patterns LP may be divided into the first and second sub-stacking patterns L1 and L2, which are respectively disposed at both sides of the vertical holes H.

Referring back to FIG. 24, the vertical structures VS may fill the vertical holes H. As an example, each of the vertical structures VS may include the vertical conductive line VC, the variable resistance element VR, and the selection element SW. The formation of the vertical structures VS may include forming the variable resistance element VR, forming the selection element SW, and forming the vertical conductive line VC. The formation of the vertical structure may further include forming the first capping structure CS1 and the second capping structure CS2.

According to an embodiment of the inventive concept, a variable resistance element and a stacking pattern may be uniformly deposited throughout the entire region. Accordingly, it may be possible to control a contact area between the variable resistance element and the stacking pattern and thereby to control power consumption in a variable resistance memory device.

While example embodiments of the inventive concept have been particularly shown and described, it will be understood by one of ordinary skill in the art that variations in form and detail may be made therein without departing from the spirit and scope of the present disclosure.

What is claimed is:

1. A variable resistance memory device, comprising:
a stacking pattern disposed on a substrate;
a vertical structure extended in a first direction, that is perpendicular to a top surface of the substrate, and penetrating the stacking pattern; and
a horizontal conductive line disposed adjacent to the stacking pattern and extended in a second direction that is parallel to the top surface of the substrate,
wherein the vertical structure comprises a vertical conductive line penetrating the stacking pattern, a variable resistance element at least partially enclosing the vertical conductive line, and a selection element interposed between the vertical conductive line and the variable resistance element,
wherein each of the vertical conductive line, the variable resistance element, and the selection element extends in the first direction, and
wherein the stacking pattern is electrically connected to the horizontal conductive line and extends along the horizontal conductive line and in the second direction.

2. The variable resistance memory device of claim 1, wherein the stacking pattern comprises a two dimensional material.

3. The variable resistance memory device of claim 2, wherein the two dimensional material comprises graphene and/or transition metal dichalcogenides (TMD).

4. The variable resistance memory device of claim 1, wherein the vertical structure includes a plurality of vertical structures spaced apart from each other in the second direction, and
wherein the stacking pattern comprises a line portion, which extends in the second direction, and protruding portions, which extend from the line portion toward the plurality of vertical structures, respectively.

5. The variable resistance memory device of claim 1, wherein the stacking pattern is in direct contact with the variable resistance element of the vertical structure.

6. The variable resistance memory device of claim 1, further comprising an insulating pattern disposed on top or bottom surfaces of the stacking pattern,
wherein the insulating pattern is in direct contact with the variable resistance element of the vertical structure.

7. The variable resistance memory device of claim 1, wherein the horizontal conductive line is in direct contact with top or bottom surfaces of the stacking pattern.

8. The variable resistance memory device of claim 1, further comprising a sacrificial pattern interposed between the horizontal conductive line and the vertical structure.

9. The variable resistance memory device of claim 1, wherein the horizontal conductive line is horizontally spaced apart from the vertical structure.

10. The variable resistance memory device of claim 1, wherein the horizontal conductive line is linearly extended in the second direction.

11. The variable resistance memory device of claim 1, wherein the vertical structure includes a plurality of vertical structures spaced apart from each other in the second direction, and
wherein the horizontal conductive line comprises a line portion, which extends in the second direction, and protruding portions, which extend from the line portion toward the plurality of vertical structures, respectively.

12. The variable resistance memory device of claim 1, wherein the vertical structure further comprises a first capping structure interposed between the variable resistance element and the selection element.

13. The variable resistance memory device of claim 1, wherein the vertical structure further comprises a second capping structure interposed between the vertical conductive line and the selection element.

14. The variable resistance memory device of claim 1, wherein the stacking pattern is a first stacking pattern,
wherein the variable resistance memory device further comprises a second stacking pattern, which is spaced apart from the first stacking pattern in the first direction, and
wherein a first thickness of the first stacking pattern is different from a second thickness of the second stacking pattern.

15. A variable resistance memory device, comprising:
stacking patterns disposed on a substrate, the stacking patterns comprising a first stacking pattern and a second stacking pattern, which is spaced apart from the first stacking pattern in a first direction that is perpendicular to a top surface of the substrate;
a vertical structure extended in the first direction and penetrating the stacking patterns; and
horizontal conductive lines extended in a second direction, which is parallel to the top surface of the substrate, and disposed adjacent to the stacking patterns, respectively,
wherein the vertical structure comprises a vertical conductive line penetrating the stacking patterns, a variable resistance element enclosing the vertical conductive line, and a selection element interposed between the vertical conductive line and the variable resistance element,
wherein each of the vertical conductive line, the variable resistance element, and the selection element extends in the first direction, and
wherein a first thickness of the first stacking pattern in the first direction is different from a second thickness of the second stacking pattern in the first direction.

16. The variable resistance memory device of claim 15, wherein the stacking patterns comprise a two dimensional material.

17. The variable resistance memory device of claim 15, wherein the first stacking pattern is disposed on the second stacking pattern, and
wherein the first thickness is smaller than the second thickness.

18. The variable resistance memory device of claim 15, wherein the first stacking pattern is disposed on the second stacking pattern, and
wherein the first thickness is larger than the second thickness.

19. A variable resistance memory device, comprising:
stacking patterns, which are stacked on a substrate and are spaced apart from each other in a first direction that is perpendicular to a top surface of the substrate; and
a vertical structure, which extends in the first direction and penetrates the stacking patterns,
wherein the vertical structure comprises a vertical conductive line penetrating the stacking patterns, a variable resistance element enclosing the vertical conductive line, and a selection element interposed between the vertical conductive line and the variable resistance element,
wherein each of the vertical conductive line, the variable resistance element, and the selection element extends in the first direction, and
wherein each of the stacking patterns extends in a second direction parallel to the top surface of the substrate and comprises a two dimensional material.

20. The variable resistance memory device of claim 19, further comprising insulating patterns,
wherein the insulating patterns and the stacking patterns are alternately stacked in the first direction, and
wherein top and bottom surfaces of the stacking patterns are in contact with the insulating patterns.
